(19) United States
(12) Patent Application Publication
(10) Pub. No.: US 2011/0226307 A1
(43) Pub. Date: Sep. 22, 2011

(54) THREE-DIMENSIONAL TYPE CONCENTRATING SOLAR CELL SYSTEM

(75) Inventor: Tai Hui LIU, Hsinchu County (TW)

(73) Assignee: SOLAPOINT CORPORATION, Hsinchu County (TW)

(21) Appl. No.: 12/727,727

(22) Filed: Mar. 19, 2010

(51) Int. Cl. H01L 31/052

(52) U.S. Cl. 136/246

(57) ABSTRACT

A three-dimensional type concentrating solar cell system without sun-tracing apparatus is provided. The system comprises a plurality of sphere-like concentrators and a plurality of photovoltaic cell. The sphere-like concentrators are arranged to form a curved surface. There is no need for the system to trace the light source, such as the sun. The present invention can provide sufficient electric power for user's applications.

### BACKGROUND OF THE INVENTION

1. Field of the Invention

The present invention is generally related to wide-angle light collecting optical design and alignment to the light source, and more particularly to a photoelectronic device using and tightly arranging a plurality of sphere-like concentrators to form a curve surface. The device can be applied to concentrating sun lights or indoor light rays to generate electric power.

2. Description of the Prior Art

Energy generated from solar cell is commonly known as a better and clean energy than other power resources, such as fossil fuel power, nuclear energy power, or hydraulic power. Solar power can be much more superior when the continuing inflation of crude oil. Further, oil is bound to exhaust soon or later, but the solar power, on the other side, is exhaustless power resources compared to petrifaction power. Hence, many governments, research/development units, and private enterprises put numerous research resources into the solar power industry.

For high material cost of photovoltaic cell, and in order to cost down such that the solar power can be commercialized and more popular to staple commodity, now a method is provided to use optical concentrating system to reduce high material cost of using solar cell. The simplest way is to use relative large area of lens to collect lights such that a larger area of lights can be concentrated into a relative smaller area of photovoltaic cell as to increase the power generating efficiency. Nevertheless, due to mass volume and weight of lens, cumbersome solar power generating system is incurred. Furthermore, issues come from conventional lens optical system, such as aberration, chromatic aberration, or focus, can be raised as well. Therefore, some research topics turn to other optical concentrating system to solve the issues above mentioned.

One simple solution is to use Fresnel lens to replace traditional lens. Please refer to FIG. 1, a Fresnel lens 10 focuses lights into a photovoltaic cell 13, wherein thickness of the Fresnel lens 10 can be decreased compared to the traditional lens and larger volume as well as mass of the traditional lens can be reduced significantly. Another solution, provided by Fork and Maeda, uses Cassegrain system as solar collecting system to concentrate lights. The solution they provided can be referred to US Pub. No. 2006/0231133, wherein a primary mirror and a secondary mirror are used to collect lights into photovoltaic cell. Please refer to FIG. 2, a photovoltaic cell 13 is located at the bottom region of a primary mirror 11, and a secondary mirror 12 is located above the primary mirror 11. Lights are irradiated onto the primary mirror 11 and reflected from the secondary mirror 12 into the photovoltaic cell 13.

Two designs of traditional concentrating solar cell module mentioned above have limitation to use high precision solar tracking system, with lens or mirror vertical or perpendicular to incident lights such that solar lights can be concentrated into chip to transform solar lights into electric power. Generally, cost on solar tracking system is about one-fifth of the total cost of all concentrating solar cell module. The more the magnification ratio of the concentrating device is, the more solar tracking precision is, and deviation tolerance decreases. For example, the Earth spins 24 hours a day, and the Sun moves relatively to the Earth at about 15 degree per hour, that is 0.25 degree per minute (unit of time). When magnification ratio of the concentrating device is about 1000, the precision per minute is about 0.9 second.

Therefore, the more magnification ratio of the concentrating device is, the higher precision of the solar-tracking system is. The cost of total concentrating solar cell module will increase significantly and making the concentrating solar cell module not easy to be commercialized.

### SUMMARY OF THE INVENTION

According to the issues raised from the prior art and accommodating to requirement of industrial benefit, this invention provides a three-dimensional type concentrating solar cell system without using a complex solar tracking system. The system may be characterized by that a plurality of sphere-like concentrators are applied and tightly arranged to form a curved surface.

Accordingly, the present invention discloses a three-dimensional type concentrating solar cell system with a plurality of sphere-like concentrators and a plurality of photovoltaic cells. The system comprises a plurality of sphere-like concentrators for concentrating a plurality of light rays respectively. The sphere-like concentrators are arranged side by side to form a curved surface. Each of the photovoltaic cells is for receiving each of the concentrated light rays from the sphere-like concentrators, and is for transferring each of the concentrated light rays into electric power.

The present invention further discloses a three-dimensional type concentrating solar cell system. The system comprises a plurality of photovoltaic cells and a plurality of rows of sphere-like concentrators for concentrating a plurality of light rays respectively. The sphere-like concentrators in each of the rows are arranged side by side to form a curved line. The curved lines of sphere-like concentrators are arranged side by side to form a curve surface. Each of the photovoltaic cells is for receiving each of the concentrated light rays from the sphere-like concentrators, and is for transferring each of the concentrated light rays into electric power.

The present invention further discloses a three-dimensional type concentrating solar cell system. The system comprises a plurality of photovoltaic cells and a plurality of rows of sphere-like concentrators for concentrating a plurality of light rays respectively. The sphere-like concentrators in each of the rows are arranged side by side to form a linear line. The linear lines of sphere-like concentrators are arranged side by side to form at least one part of a cylindrical surface. Each of the photovoltaic cells is for receiving each of the concentrated light rays from said sphere-like concentrators, and is for transferring each of the concentrated light rays into electric power.

### BRIEF DESCRIPTION OF THE DRAWINGS

FIG. 1 illustrates a cross-sectional structure view of one traditional concentrating solar cell system;

FIG. 2 illustrates a cross-sectional structure view of another traditional concentrating solar cell system;

FIG. 3 schematically illustrates reducing light-receiving area on a photovoltaic cell of a corresponding sphere-like concentrator while light source significantly moves.

FIG. 4A schematically illustrates that a cutting face 101A is formed by removing non-concentrating periphery of the first type transparent sphere.

FIG. 4B schematically illustrates that a plurality of first type transparent spheres can be tightly arranged side by side to form a curved surface by the cutting face 101A.

FIG. 5 schematically illustrates a cutting face 101B is formed by removing a concentrating portion of a second type transparent sphere.

FIG. 6A schematically illustrates a plurality of first typetransparent spheres each having four cutting faces are tightly arranged side by side to from a curved surface;

FIG. 6B schematically illustrates a plurality of first type transparent spheres each having six cutting faces are tightly arranged side by side to from a curved surface;

FIG. 7 illustrates a plurality of sphere-like concentrators are arranged side by side to form a curved surface, and the surface may be a cylindrical surface (a), a conical surface (b), a spherical surface (c), an ellipsoid surface (d) and a hand-ring surface (e);

FIG. 8A schematically illustrates that the three-dimensional type concentrating solar cell system further comprises a spherical housing. The sphere-like concentrators are installed on an inner surface of the spherical housing.

FIG. 8B schematically illustrates that the sphere-like concentrators are installed inside the upper hemisphere of the spherical housing according to the first embodiment of the present invention. The lower hemisphere is filled with a load.

FIG. 9A schematically illustrates the three-dimensional type concentrating solar cell system further comprises a hand-ring-shaped housing. The sphere-like concentrators are installed on the inner surface of the hand-ring-shaped housing according to the first embodiment of the present invention.

FIG. 9B schematically illustrates a plurality of sphere-like concentrators are installed inside the upper portion of the hand-ring-shaped housing according to the first embodiment of the present invention. The lower portion is filled with a load.

FIG. 10A schematically illustrates the three-dimensional type concentrating solar cell system further comprises a cylindrically-shaped housing. The sphere-like concentrators are installed on the inner surface of the cylindrically-shaped housing according to the first embodiment of the present invention.

FIG. 10B schematically illustrates a plurality of sphere-like concentrators are installed inside the upper portion of the cylindrically-shaped housing according to the first embodiment of the present invention. The lower portion is filled with a load.

FIG. 11 illustrates a plurality of sphere-like concentrators in each of the rows are first arranged side by side to form a curved line according to a second embodiment of the present invention. The curved lines of sphere-like concentrators are then arranged side by side to form a curved surface, such as an ellipsoid surface (a), a hand-ring surface (b) and a cylindrical surface (c);

FIG. 12 schematically illustrates that the photovoltaic cells 130 are between the bar-shaped substrate 140 and the curved line 101-1 of sphere-like concentrators according to the second embodiment of the present invention;

FIG. 13A schematically illustrates that a plurality of sphere-like concentrators in each of the rows are first arranged side by side to form a linear line 101-2 in the third embodiment according to a third embodiment of the present invention. The linear lines 101-2 of sphere-like concentrators are arranged side by side to form at least one part of a cylindrical surface;

FIG. 13B schematically illustrates that the photovoltaic cells 130 are between the bar-shaped substrate 140 and the linear line 101-2 of sphere-like concentrators according to the third embodiment of the present invention;

FIG. 14A schematically illustrates that a long symmetry axis P is parallel with a long-axis direction Q of the linear line of sphere-like concentrators according to the third embodiment of the present invention; and

FIG. 14B schematically illustrates that a long symmetry axis P is perpendicular with a long-axis direction Q of the linear line of sphere-like concentrators according to the third embodiment of the present invention.

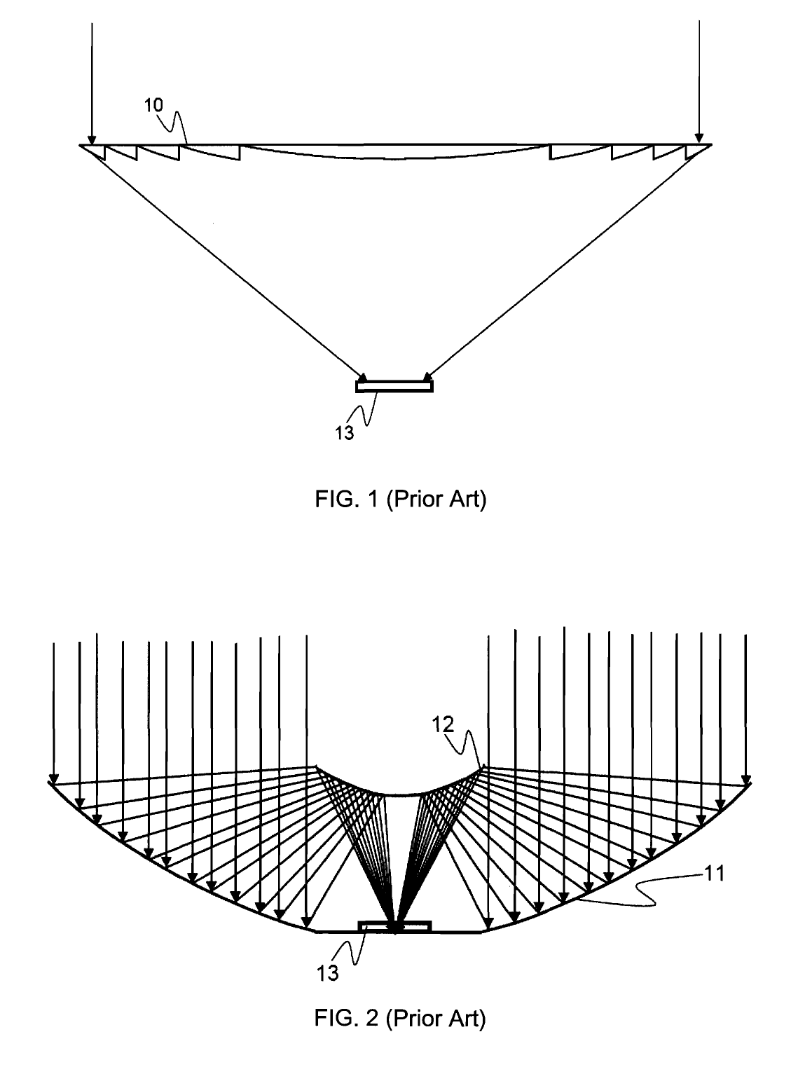

### DESCRIPTION OF THE PREFERRED EMBODIMENTS

What is probed into the invention is a three-dimensional type concentrating solar cell system without using a complex solar tracking system. Detailed descriptions of the structure and elements will be provided in the following in order to make the invention thoroughly understood. Obviously, the application of the invention is not confined to specific details familiar to those skilled in the art of concentrating solar cell system. On the other hand, the common structures and elements that are known to everyone are not described in details as to avoid unnecessary limitations to the invention.

Preferred embodiments of the present invention will be described in detail. However, in addition to the detail description, the present invention may be widely applied to other embodiments. The scope of the present invention is not limited. It is limited solely by the appended claims.

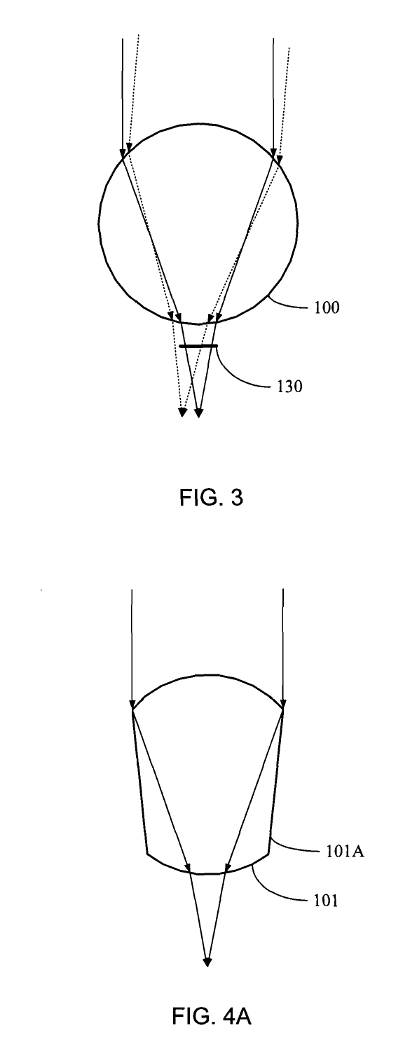

This invention makes use of a plurality of sphere-like concentrators. When the relative position between the light source and the sphere-like concentrator is changed, there is no need to move or rotate the concentrator, and the light ray can still be focused on the other side of the concentrator. By using this means, the significance of orientation of light source to the plurality of transparent spheres can be decreased materially. However, to determine efficiency of a solar cell system, an actual light-receiving area is also an important factor. As shown in FIG. 3, dotted lines show reducing light-receiving area of a photovoltaic cell 130 on a corresponding sphere-like concentrator (e.g. transparent spheres 100) while light source significantly moves. To overcome this obstacle, a plurality of sphere-like concentrators are arranged side by side to form a curved surface in the invention. On the curved surface, suitable sphere-like concentrators and their corresponding photovoltaic cells always can be found to be operated when light source moves with a variety of angles.

The traditional high precision solar-tracking systems cost much higher. The present invention provides means to solve this problem, thereby reducing the cost significantly.

In the present invention, each of the described “sphere-like concentrators” is a transparent sphere 100, or is a transparent sphere at least having a cutting face 101.

According to positions of different cutting faces, a transparent sphere at least having a cutting face may have a first type, a second type and a third type.

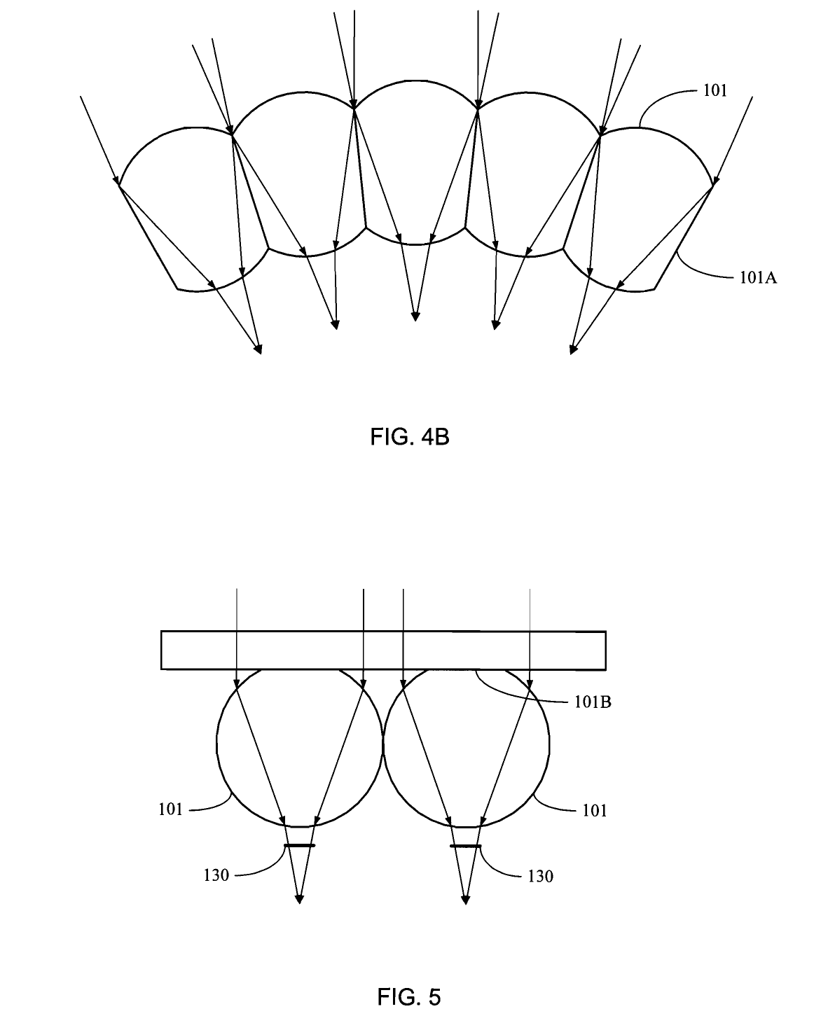

Referring to FIG. 4A, a cutting face 101A is formed by removing non-concentrating periphery of the first type transparent sphere. By the cutting face 101A, a plurality of first type transparent spheres can be tightly arranged side by side (As shown in FIG. 4B) to form a curved surface. It is noted that the inclined angle of the cutting face 101A determines the curvature of the curve surface.

Referring to FIG. 5, a cutting face 101B is formed by removing a concentrating portion of a second type transparent sphere. By the cutting face 101B, the second type transparent sphere can be tightly combined to other devices of the three-dimensional type concentrating solar cell system.

According to a practical use, a cutting face may also be formed by simultaneously removing a concentrating portion and non-concentrating periphery of a third type transparent sphere.

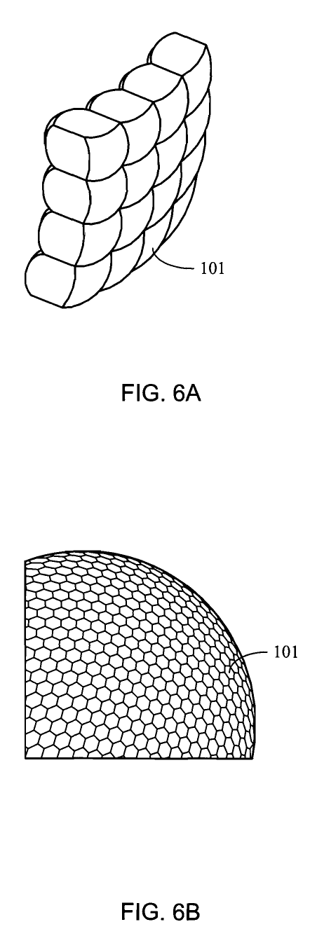

Being observed along a light concentrating direction, the first type transparent sphere 101 at least having a cutting face may have a variety of shapes. Referring to FIG. 6A, for example, a plurality of first-type transparent spheres each having four cutting faces are tightly arranged side by side to from a curved surface.

Referring to FIG. 6B, when a larger number of first type transparent spheres 101 should be applied and should be arranged in a most tight way, like a compound eye of a fly. The structure is formed by removing six sides of each of the first type transparent spheres and contacting each of the partially removed transparent spheres with the other six partially removed transparent spheres.

The material used for each of the sphere-like concentrators can be glass, quartz, plastic, acrylic, PET, PU, mCOC, epoxy, silicone, PMMA, PC, CaF crystal, or MgF crystal. The each of the sphere-like concentrators can be a hollow spherical shell filled with liquid or solid as to change the refractive index of the transparent sphere. The each of the sphere-like concentrators can be manufactured by using an inject-molding method or a grinding method.

Please referring to the drawings, detailed descriptions, technical elements and a variety of embodiments will be provided as follows.

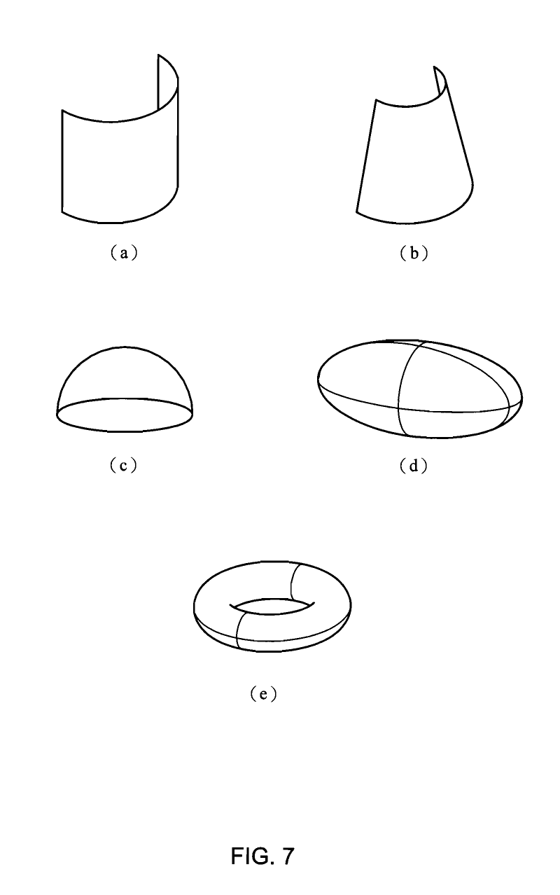

In the present invention, a first embodiment discloses a three-dimensional type concentrating solar cell system. The system comprises a plurality of sphere-like concentrators for concentrating a plurality of light rays respectively, and comprises a plurality of photovoltaic cells. The sphere-like concentrators are arranged side by side to form a curved surface. Each of the photovoltaic cells is for receiving each of the concentrated light rays from the sphere-like concentrators, and is for transferring the each of the concentrated light rays into electric power. Referring to FIG. 7, (a) to (e), the curved surface comprises at least a part of a surface selected from the group consisting of a cylindrical surface, a conical surface, a spherical surface, an ellipsoid surface and a hand-ring surface.

In the first embodiment, a plurality of sphere-like concentrators are arranged side by side to form a curved surface, there is no need for the system to trace the light source. The present invention may have more advantages. For example, traditional floating bodies (float ball, float camel and other shapes of floating bodies) may be substituted according to the present invention. As an example, traditional float balls may comprise float balls for fishing net, observation, marking, positioning and so on. The traditional float balls provide functions of only floating or protecting inside elements. With functions of a solar cell, a float ball may have more applications and commercial values. Moreover, a float ball with functions of a solar cell may be combined with other lighting device such as LED lamp, to form a sign lamp floated on water.

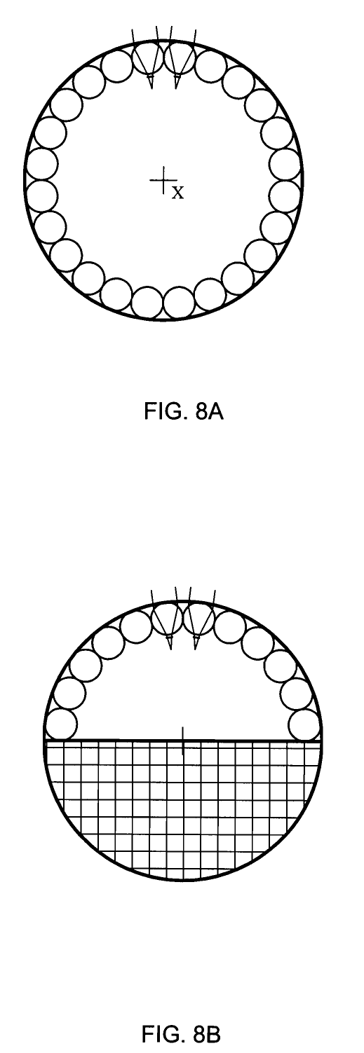

In the first embodiment, Referring to FIG. 8A, for example, the three-dimensional type concentrating solar cell system further comprises a spherical housing having a center X and an inner surface. The sphere-like concentrators are installed on the inner surface of the spherical housing. The photovoltaic cells are arranged inside the spherical housing. The sphere-like concentrators are equally away from the center X of the spherical housing. The spherical housing is for protecting the sphere-like concentrators and photovoltaic cells therein. The spherical housing is made of a transparent material for being entered with light rays. To serve a three-dimensional type concentrating solar cell as a float ball on sea surface, the sphere-like concentrators are fully distributed on the inner surface of the spherical housing. In the float ball, suitable sphere-like concentrators and their corresponding photovoltaic cells always can be found to receive light rays and to transferring the light rays into electric power, no matter how the sea waves tumble.

To tightly combine the sphere-like concentrators with the spherical housing, it is noted that a second type transparent sphere at least having a cutting face may be applied. On the other hand, the first type and the second type transparent spheres may be simultaneously applied, thereby tightly arranging the sphere-like concentrators to form a big spherical surface, and to tightly contact with the spherical housing.

Referring to FIG. 8B, for another example, the spherical housing has a lower hemisphere and an upper hemisphere. The sphere-like concentrators are installed inside the upper hemisphere of the spherical housing. The lower hemisphere is filled with a load. The center of gravity is lowered by the load, so that the sea-surface float ball may stably floats on water to keep the upper hemisphere always be up. The usage quantities of the sphere-like concentrators and the photovoltaic cells are therefore reduced to lower production cost. Alternatively, the sphere-like concentrators may be installed on only a part of the upper hemisphere to further reduce the production cost.

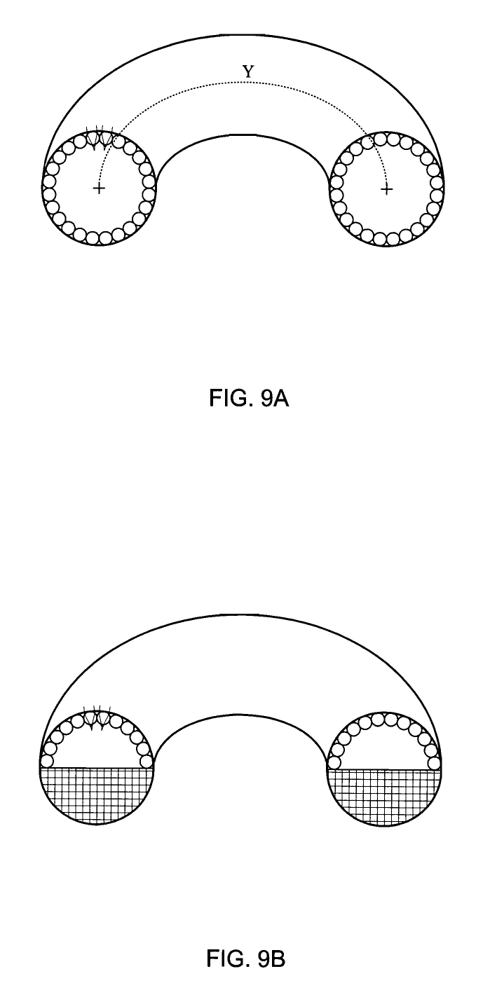

Referring to FIG. 9A, another similar example may be that the three-dimensional type concentrating solar cell system further comprises a hand-ring-shaped housing having an inner surface and a cross-sectional plane center Y, wherein the sphere-like concentrators are installed on the inner surface of the hand-ring-shaped housing, and wherein the photovoltaic cells are arranged inside the hand-ring-shaped housing, and wherein the sphere-like concentrators are equally away from the cross-sectional plane center Y.

The hand-ring-shaped housing is for protecting the sphere-like concentrators and photovoltaic cells therein. The hand-ring-shaped housing, made of a transparent material for being entered with light rays, may serve as a life buoy. As another example, the system may be combined with other lighting device such as an LED lamp, so that the system may be charged by solar energy in the daytime and emit light rays at night. The combination-type system is especially suitable for seaway rescue.

Referring to FIG. 9B, in this example, the hand-ring-shaped housing has a lower portion and an upper portion. The sphere-like concentrators are installed inside the upper portion of the hand-ring-shaped housing. The lower portion is filled with a load. The upper portion of hand-ring-shaped housing is kept up. By doing so, the usage quantities of the sphere-like concentrators and the photovoltaic cells are reduced to lower production cost

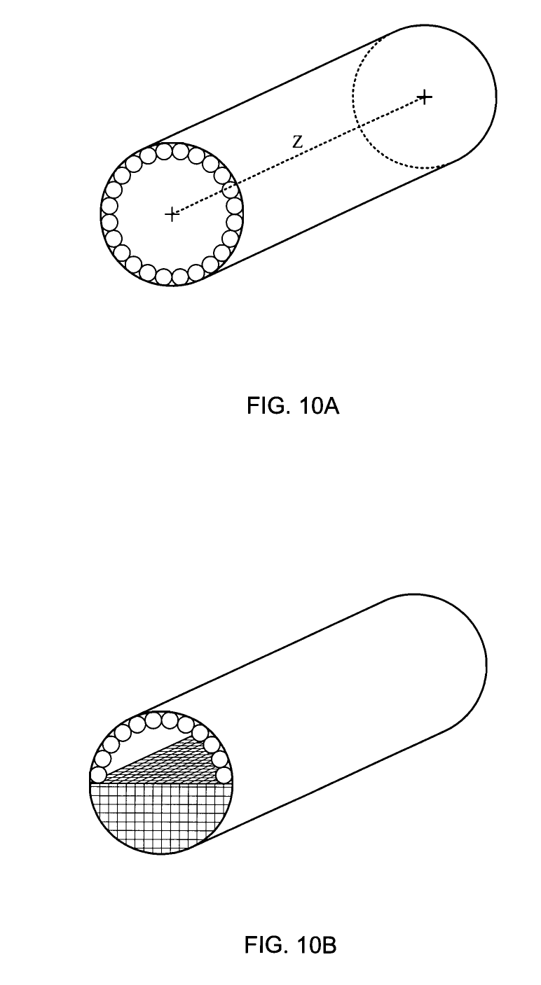

Referring to FIG. 10A and FIG. 10B, a similar example may be that the three-dimensional type concentrating solar cell system further comprises a cylindrically-shaped housing having a central axis Z and an inner surface. The sphere-like concentrators are installed on the inner surface of the cylindrically-shaped housing, and wherein the photovoltaic cells are arranged inside the cylindrically-shaped housing, and wherein the sphere-like concentrators are equally away from the center axis Z of the cylindrically-shaped housing. Moreover, the cylindrically-shaped housing has a lower portion and an upper portion. The sphere-like concentrators are installed inside the upper portion of the spherical housing. The lower portion is filled with a load.

A second embodiment of the present invention discloses a three-dimensional type concentrating solar cell system. The system comprises a plurality of photovoltaic cells and a plurality of rows of sphere-like concentrators for concentrating a plurality of light rays respectively. The sphere-like concentrators in each of the rows are arranged side by side to form a curved line. The curved lines of sphere-like concentrators are arranged side by side to form a cylindrical surface. Each of the photovoltaic cells is for receiving each of the concentrated light rays from the sphere-like concentrators, and is for transferring the each of the concentrated light rays into electric power. The curved surface comprises at least a part of a surface selected from the group consisting of a cylindrical surface, a conical surface, a spherical surface, an ellipsoid surface and a hand-ring surface.

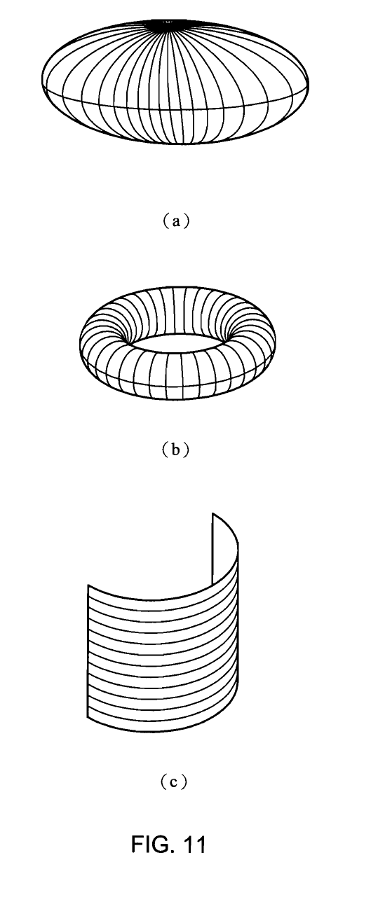

The second embodiment is similar to the first embodiment. In the first and the second embodiments, a plurality of sphere-like concentrators are tightly arranged to form a curved surface. A spherical housing, a hand-ring-shaped housing or a cylindrical housing may be added so that the sphere-like concentrators are installed on the inner surface of the housing. Alternatively, the sphere-like concentrators are installed inside the upper portion of the housing. The lower portion of the housing is filled with a load. The difference between the first and the second embodiments comprises that the sphere-like concentrators in each of the rows are first arranged side by side to form a curved line in the second embodiment. The curved lines of sphere-like concentrators are then arranged side by side to form a curved surface. Referring to FIG. 11, as schematically shown in (a) to (c), the curved lines of sphere-like concentrators are arranged to form an ellipsoid surface, a hand-ring surface and a cylindrical surface. The curved lines arrangement makes ease to change curvature or to combine to form specific curved surface, or ease for subsequent combination.

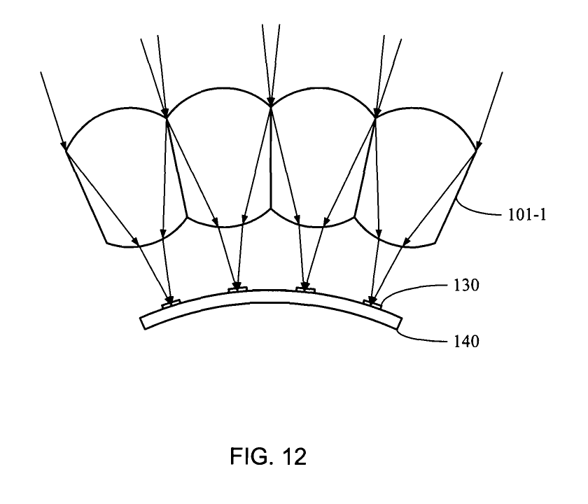

Referring to FIG. 12, as an example of the second embodiment, each curved line 101-1 is above a bar-shaped substrate 140. The photovoltaic cells 130 are between the bar-shaped substrate 140 and the curved line 101-1. The use of the bar-shaped substrate 140 has an advantage in which the photovoltaic cells 130 may be first arranged on the bar-shaped substrate 140 for subsequent aligning and combining of the sphere-like concentrators.

A third embodiment of the present invention discloses a three-dimensional type concentrating solar cell system. The system comprises a plurality of photovoltaic cells and a plurality of rows of sphere-like concentrators for concentrating a plurality of light rays respectively. The sphere-like concentrators in each of the rows are arranged side by side to form a linear line, and wherein the linear lines of sphere-like concentrators are arranged side by side to form at least one part of a cylindrical surface. Furthermore, each of the photovoltaic cells is for receiving each of the concentrated light rays from the sphere-like concentrators, and is for transferring the each of the concentrated light rays into electric power.

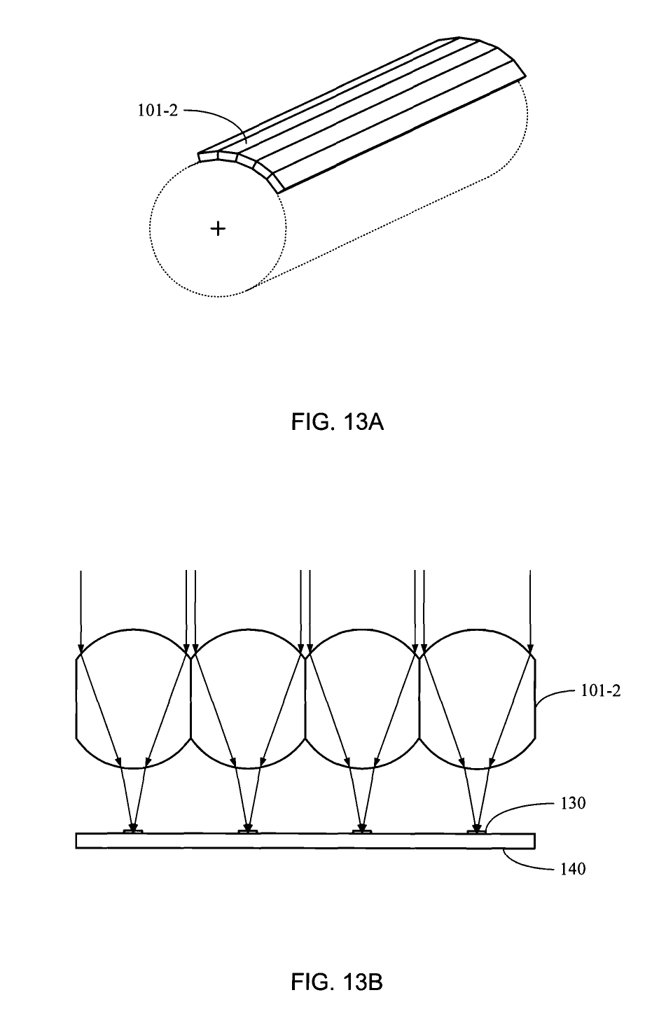

The third embodiment is similar to the second embodiment. Referring to FIG. 13A, the difference between the third and the second embodiments comprises that the sphere-like concentrators in each of the rows are first arranged side by side to form “linear line” 101-2 in the third embodiment. The linear lines of sphere-like concentrators are arranged side by side to form at least one part of a cylindrical surface.

Referring to FIG. 13B, as an example of the third embodiment, each linear line 101-2 is above a bar-shaped substrate 140. The photovoltaic cells 130 are between the bar-shaped substrate 140 and the linear line 101-2. The use of the bar-shaped substrate 140 has an advantage in which the photovoltaic cells 130 may be first arranged on the bar-shaped substrate 140 for subsequent aligning and combining of the sphere-like concentrators.

As another example of the third embodiment, the light source may be sun light. According to the Latitude of a location where the system is operated, the linear lines of sphere-like concentrators are arranged side by side to form at least one part of a cylindrical surface. Each of the linear lines may cover the traces generated by the movement of the sun in at least four hours every day in one season. Four of the linear lines are enough to cover the traces generated by the movement of the sun in one year.

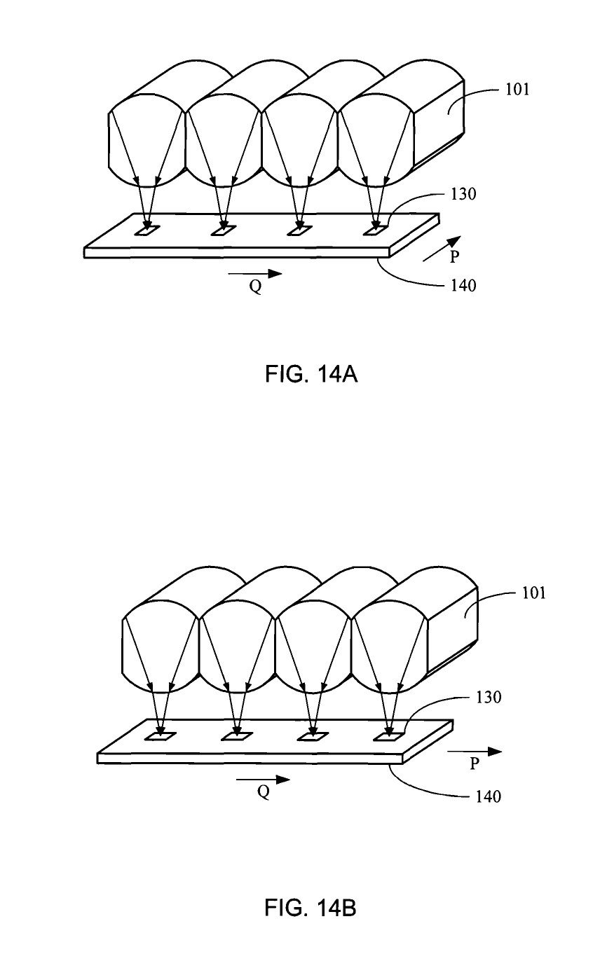

As mentioned above, an actual light-receiving area is an important factor to determine efficiency of a solar cell system. Reducing light-receiving area usually occurs on a photovoltaic cell of a corresponding sphere-like concentrator while light source significantly moves (as shown in FIG. 3). Referring to FIG. 14A to FIG. 14B, in one example of the third embodiment, each of photovoltaic cells is substantially rectangular and has a long symmetry axis P and a short symmetry axis. To overcome the problem of reducing light-receiving area, the long symmetry axis P is parallel with a long-axis direction Q of the linear lines of sphere-like concentrators in FIG. 14B. That is, the long symmetry axis P is parallel with the trace direction of the light source. The light-receiving area of the photovoltaic cells is therefore increased. When the light source is the sun, the light-receiving time of the system can be elongated. FIG. 14A schematically illustrates the common arrangement of the photovoltaic cells, that is, the long symmetry axis P is alternatively perpendicular with a long-axis direction Q of the linear lines of sphere-like concentrators, which usually encounters the above-mentioned reducing light-receiving area problem.

Although specific embodiments have been illustrated and described herein, it is obvious many combinations and modifications of the above drawings and embodiments are possible in light of the above teachings. Those combinations and modifications are also embodiments of the present invention.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A three-dimensional type concentrating solar cell system, comprising:
a plurality of sphere-like concentrators for concentrating a plurality of light rays respectively, wherein said sphere-like concentrators are arranged side by side to form a curved surface;
a plurality of photovoltaic cells, wherein each of said photovoltaic cells is for receiving each of the concentrated light rays from said sphere-like concentrators, and is for transferring each of the concentrated light rays into electric power.

2. The three-dimensional type concentrating solar cell system according to claim 1, wherein each of said sphere-like concentrators is a transparent sphere or a transparent sphere at least having a cutting face.

3. The three-dimensional type concentrating solar cell system according to claim 1, wherein said curved surface comprises at least a part of a surface selected from the group consisting of a cylindrical surface, a conical surface, a spherical surface, an ellipsoid surface and a hand-ring surface.

4. The three-dimensional type concentrating solar cell system according to claim 1, further comprising a spherical housing having a center and an inner surface, wherein said sphere-like concentrators are installed on said inner surface of said spherical housing, and wherein said photovoltaic cells are arranged inside said spherical housing, and wherein said sphere-like concentrators are equally away from said center of said spherical housing.

5. The three-dimensional type concentrating solar cell system according to claim 4, wherein said spherical housing has a lower hemisphere and an upper hemisphere, and wherein said sphere-like concentrators are installed inside said upper hemisphere of said spherical housing, and wherein the lower hemisphere is filled with a load.

6. The three-dimensional type concentrating solar cell system according to claim 1, further comprising a hand-ring-shaped housing having an inner surface and a cross-sectional plane center, wherein said sphere-like concentrators are installed on said inner surface of said hand-ring-shaped housing, and wherein said photovoltaic cells are arranged inside said hand-ring-shaped housing, and wherein said sphere-like concentrators are equally away from said cross-sectional plane center.

7. The three-dimensional type concentrating solar cell system according to claim 6, wherein said hand-ring-shaped housing has a lower portion and an upper portion, and wherein said sphere-like concentrators are installed inside said upper portion of said spherical housing, and wherein the lower portion is filled with a load.

8. The three-dimensional type concentrating solar cell system according to claim 1, further comprising a cylindrically-shaped housing having a center axis and an inner surface, wherein said sphere-like concentrators are installed on said inner surface of said cylindrically-shaped housing, and wherein said photovoltaic cells are arranged inside said cylindrically-shaped housing, and wherein said sphere-like concentrators are equally away from said center axis of said cylindrically-shaped housing.

9. The three-dimensional type concentrating solar cell system according to claim 8, wherein said cylindrically-shaped housing has a lower portion and an upper portion, and wherein said sphere-like concentrators are installed inside said upper portion of said spherical housing, and wherein the lower portion is filled with a load.

10. A three-dimensional type concentrating solar cell system, comprising:
a plurality of rows of sphere-like concentrators for concentrating a plurality of light rays respectively, wherein the sphere-like concentrators in each of said rows are arranged side by side to form a curved line, and wherein said curved lines of sphere-like concentrators are arranged side by side to form a curve surface; and
a plurality of photovoltaic cells, wherein each of said photovoltaic cells is for receiving each of the concentrated light rays from said sphere-like concentrators, and is for transferring each of the concentrated light rays into electric power.

11. The three-dimensional type concentrating solar cell system according to claim 10, wherein each of said sphere-like concentrators is a transparent sphere or a transparent sphere at least having a cutting face.

12. The three-dimensional type concentrating solar cell system according to claim 10, wherein each curved line of sphere-like concentrators is above a bar-shaped substrate, and wherein said photovoltaic cells are arranged between said bar-shaped substrate and said curved line.

13. The three-dimensional type concentrating solar cell system according to claim 10, wherein said curved surface comprises at least a part of a surface selected from the group consisting of a cylindrical surface, a conical surface, a spherical surface, an ellipsoid surface and a hand-ring surface.

14. The three-dimensional type concentrating solar cell system according to claim 10, further comprising a spherical housing having a center and an inner surface, wherein said curved lines of sphere-like concentrators are installed on said inner surface of said spherical housing, and wherein said photovoltaic cells are arranged inside said spherical housing, and wherein said sphere-like concentrators are equally away from said center of said spherical housing.

15. The three-dimensional type concentrating solar cell system according to claim 14, wherein said spherical housing has a lower hemisphere and an upper hemisphere, and wherein said sphere-like concentrators are installed inside said upper hemisphere of said spherical housing, and wherein the lower hemisphere is filled with a load.

16. The three-dimensional type concentrating solar cell system according to claim 10, further comprising a hand-ring-shaped housing having an inner surface and a cross-sectional plane center, wherein said curved lines of sphere-like concentrators are installed on said inner surface of said hand-ring-shaped housing, and wherein said photovoltaic cells are arranged inside said hand-ring-shaped housing, and wherein said sphere-like concentrators are equally away from said cross-sectional plane center.

17. The three-dimensional type concentrating solar cell system according to claim 16, wherein said hand-ring-shaped housing has a lower portion and an upper portion, and wherein said curved lines of sphere-like concentrators are installed inside said upper portion of said spherical housing, and wherein the lower portion is filled with a load.

18. The three-dimensional type concentrating solar cell system according to claim 10, further comprising a cylindrically-shaped housing having a center axis and an inner surface, wherein said curved lines of sphere-like concentrators are installed on said inner surface of said cylindrically-shaped housing, and wherein said photovoltaic cells are arranged inside said cylindrically-shaped housing, and wherein said sphere-like concentrators are equally away from said center axis of said cylindrically-shaped housing.

19. The three-dimensional type concentrating solar cell system according to claim 18, wherein said cylindrically-shaped housing has a lower portion and an upper portion, and wherein said curved lines of sphere-like concentrators are installed inside said upper portion of said spherical housing, and wherein the lower portion is filled with a load.

20. A three-dimensional type concentrating solar cell system, comprising:
a plurality of rows of sphere-like concentrators for concentrating a plurality of light rays respectively, wherein the sphere-like concentrators in each of said rows are arranged side by side to form a linear line, and wherein said linear lines of sphere-like concentrators are arranged side by side to form at least one part of a cylindrical surface; and
a plurality of photovoltaic cells, wherein each of said photovoltaic cells is for receiving each of the concentrated light rays from said sphere-like concentrators, and is for transferring each of the concentrated light rays into electric power.

21. The three-dimensional type concentrating solar cell system according to claim 20, wherein each of said sphere-like concentrators is a transparent sphere or a transparent sphere at least having a cutting face.

22. The three-dimensional type concentrating solar cell system according to claim 20, wherein each of photovoltaic cells is substantially rectangular and has a long symmetry axis and a short symmetry axis, and wherein said long symmetry axis is parallel with said linear lines of said sphere-like concentrators.

23. The three-dimensional type concentrating solar cell system according to claim 20, wherein each linear line is above a bar-shaped substrate, and wherein said photovoltaic cells are arranged between said bar-shaped substrate and said linear line of said sphere-like concentrators.
